(19) United States
(12) Patent Application Publication
(10) Pub. No.: US 2025/0085577 A1
(43) Pub. Date: Mar. 13, 2025

(54) DISPLAY PANEL, MANUFACTURING METHOD THEREOF, AND DISPLAY APPARATUS

(71) Applicants: Hefei BOE Display Technology Co., Ltd., Hefei, Anhui, (CN); BOE TECHNOLOGY GROUP CO., LTD., Beijing (CN)

(72) Inventors: Xin ZHOU, Beijing (CN); Jiaqing LIU, Beijing (CN); Wei ZHANG, Beijing (CN); Jilei GAO, Beijing (CN); Chao LI, Beijing (CN); Liang MA, Beijing (CN); Xipeng WANG, Beijing (CN); Benzhi XU, Beijing (CN); Liangwei ZHANG, Beijing (CN); Xing ZHANG, Beijing (CN); Yonggang ZHANG, Beijing (CN)

(21) Appl. No.: 18/580,659

(22) PCT Filed: Jul. 25, 2022
(86) PCT No.: PCT/CN2022/107645

§ 371 Date: Jan. 19, 2024

(51) Int. Cl. G02F 1/1333; G02F 1/1335; G02F 1/1339; G02F 1/1362; G02F 1/1368; H01L 27/12

(52) U.S. Cl. CPC G02F 1/133322; G02F 1/133514; G02F 1/13394; G02F 1/136286; G02F 1/1368; H10D 86/441; H10D 86/60

(57) ABSTRACT

A display panel includes an array substrate and a color filter substrate, where the color filter substrate includes a first substrate, spacer pillars, and color filter layers, each spacer pillar is in the spacing region, and each pixel region is provided with a color filter layer. Each spacer pillar includes at least one spacer layer each made of the same material as the color filter layer in one of the pixel regions. The array substrate includes a second substrate and a support layer, where the support layer is on a side of the second substrate facing the color filter substrate, and includes a body layer and a plurality of protrusions on a side of the body layer away from the second substrate, where each protrusion is each opposite to at least one of the spacer pillars. At least one of the spacer pillars is each supported on the corresponding protrusion.

### TECHNICAL FIELD

The present disclosure relates to the field of display technology, and specifically relates to a display panel, a manufacturing method thereof, and a display apparatus.

### BACKGROUND

The liquid crystal display panel is formed by filling liquid crystal between an array substrate and a color filter substrate, and then aligning and assembled the two substrates. To maintain a stable liquid crystal display panel and a uniform cell gap, post spacers are typically provided between the array substrate and the opposite substrate.

### SUMMARY

Embodiments of the present disclosure provide a display panel, a manufacturing method thereof, and a display apparatus.

In a first aspect, an embodiment of the present disclosure provides a display panel, including an array substrate and a color filter substrate opposite to each other, wherein
the color filter substrate includes a first substrate, a plurality of spacer pillars, and a plurality of color filter layers, the spacer pillars and the color filter layers are on a side of the first substrate facing the array substrate, and the first substrate includes a plurality of pixel regions and a spacing region between adjacent pixel regions; each spacer pillar is in the spacing region, and each pixel region is provided with the color filter layer;
each spacer pillar includes at least one spacer layer each made of the same material as the color filter layer in one of the pixel regions.
the array substrate includes a second substrate and a support layer, wherein the support layer is on a side of the second substrate facing the color filter substrate, and the support layer includes a body layer and a plurality of protrusions on a side of the body layer away from the second substrate, and at least one of the protrusions is each opposite to one of the spacer pillars; and
at least one of the spacer pillars is each in direct contact with a corresponding protrusion.

In some embodiments, the protrusions have a hardness lower than a hardness of the spacer layer.

In some embodiments, the protrusions are made of a material including an organic material.

In some embodiments, the body layer and the protrusions form an integral structure.

In some embodiments, a ratio of a height of each spacer pillar to a height of the corresponding protrusion is 0.5 to 1.3.

In some embodiments, the color filter substrate further includes a black matrix in the spacing region; and
each spacer pillar is on a side of the black matrix away from the first substrate, and an orthographic projection of the black matrix on the first substrate covers an orthographic projection of the spacer pillar on the first substrate.

In some embodiments, each spacer pillar is opposite to one of the protrusions;
the plurality of spacer pillars include at least one main spacer pillar and a plurality of auxiliary spacer pillars;
each main spacer pillar is in direct contact with a protrusion opposite to the main spacer pillar; and
each auxiliary spacer pillar is spaced apart from a protrusion opposite to the auxiliary spacer pillar.

In some embodiments, the color filter substrate includes color filter layers of N colors; each spacer layer corresponds to a color filter layer of one color, and different spacer layers in the same spacer pillar correspond to color filter layers of different colors; each spacer layer is made of the same material and has the same thickness as the corresponding color filter layer; and
the main spacer pillar includes N spacer layers, and each auxiliary spacer pillar includes M spacer layers, where M and N are both positive integers, and M<N.

In some embodiments, orthographic projections of the N spacer layers in the main spacer pillar on the first substrate have the same area.

In some embodiments, each spacer pillar includes a plurality of spacer layers, and
orthographic projections of the plurality of spacer layers in each of at least one of the spacer pillars on the first substrate are sequentially reduced in area in a direction away from the black matrix.

In some embodiments, a ratio of a width of a spacer layer closest to the black matrix in each spacer pillar to a width of the black matrix is between 0.5 and 1; and a ratio of an area of a spacer layer farthest from the black matrix in the spacer pillar to an area of the spacer layer closest to the black matrix is between ⅙ and ½.

In some embodiments, at least two adjacent color filter layers of the same color are connected into an integral structure.

In some embodiments, at least one of the spacer layers and an adjacent color filter layer are connected into an integral structure.

In some embodiments, the array substrate further includes a plurality of gate lines and a plurality of data lines on the second substrate, the plurality of gate lines and the plurality of data lines are intersected with each other, and an orthographic projection of each gate line on the first substrate and an orthographic projection of each data line on the first substrate are both within the spacing region; and
an orthographic projection of at least one of the spacer pillars on the first substrate is within the orthographic projection of the gate line on the first substrate.

In some embodiments, the array substrate further includes a thin film transistor, and a pixel electrode;
the thin film transistor is between the second substrate and the support layer; and
the pixel electrode is on a side of the support layer away from the second substrate, and connected to a drain of the thin film transistor through a via in the body layer.

In some embodiments, the orthographic projection of the spacer pillar on the first substrate is not overlapped with an orthographic projection of the thin film transistor on the first substrate.

In a second aspect, an embodiment of the present disclosure provides a method for manufacturing a display panel, including:
providing a first substrate including a plurality of pixel regions and a spacing region between adjacent pixel regions;
forming a plurality of spacer pillars in the spacing region of the first substrate, and forming a color filter layer in each pixel region of the first substrate, wherein each spacer pillar includes at least one spacer layer, and each spacer layer is formed synchronously with a corresponding color filter layer;
providing a second substrate, and forming a support layer on the second substrate, wherein the support layer includes a body layer and a plurality of protrusions on a side of the body layer away from the second substrate, and at least one of the protrusions is opposite to one of the spacer pillars; and
aligning and assembling the second substrate with the first substrate, so that at least one of the spacer pillars is in direct contact with a corresponding protrusion.

In some embodiments, forming the support layer on the second substrate includes:
forming a support material layer; and
patterning the support material layer to form the body layer and the plurality of protrusions on the body layer.

In a third aspect, an embodiment of the present disclosure provides a display apparatus, including the display panel according to the first aspect.

### BRIEF DESCRIPTION OF DRAWINGS

Accompanying drawings are provided for further understanding of the present disclosure and constitute a part of the specification. Hereinafter, these drawings are intended to explain the present disclosure together with the following specific implementations, but should not be considered as a limitation on the present disclosure, in which:

FIG. 1 is a schematic structural diagram of a display panel according to an embodiment of the present disclosure.

FIG. 2 is a schematic structural diagram of another display panel according to an embodiment of the present disclosure.

FIG. 3A is a schematic structural diagram of another display panel according to an embodiment of the present disclosure.

FIG. 3B is a schematic structural diagram of another display panel according to an embodiment of the present disclosure.

FIG. 4 is a schematic structural diagram of another display panel according to an embodiment of the present disclosure.

FIG. 5 is a schematic structural diagram of another display panel according to an embodiment of the present disclosure.

FIG. 6A is a schematic plan view of a display panel according to an embodiment of the present disclosure.

FIG. 6B is a schematic plan view of a display panel according to an embodiment of the present disclosure.

FIG. 6C is a schematic sectional view taken along line AA′ in FIG. 6B.

FIG. 6D is a schematic plan view of a display panel according to an embodiment of the present disclosure.

FIG. 7 is a schematic structural diagram of another display panel according to an embodiment of the present disclosure.

FIG. 8 is a schematic plan view of another display panel according to an embodiment of the present disclosure.

FIG. 9 is a schematic flowchart of a method for manufacturing a display panel according to an embodiment of the present disclosure.

### DETAIL DESCRIPTION OF EMBODIMENTS

Hereinafter, specific implementations of the present disclosure will be described with respect to the accompanying drawings. It will be appreciated that the specific implementations as set forth herein are merely for the purpose of illustration and explanation of the present disclosure and should not be constructed as a limitation thereon.

To make the objects, technical solutions and advantages of the embodiments of the present disclosure more apparent, the technical solutions according to the embodiments of the present disclosure will be clearly and completely described below with reference to the drawings of the embodiments of the present disclosure. Apparently, the described embodiments are some, but not all, of the embodiments of the present disclosure. All other embodiments obtained by those of ordinary skill in the art based on the embodiments of the present disclosure described herein without paying any creative effort shall be included in the protection scope of the present disclosure.

Unless otherwise defined, technical or scientific terms used in the embodiments of the present disclosure are intended to have general meanings as understood by those of ordinary skill in the art. The words “first”, “second” and similar terms used in the present disclosure do not denote any order, quantity, or importance, but are used merely for distinguishing different components from each other. Likewise, the word “comprising” or “including” or the like means that the element or item preceding the word contains elements or items that appear after the word or equivalents thereof, but does not exclude other elements or items. The words “connected” or “coupled” and the like are not restricted to physical or mechanical connections, but may include electrical connections, whether direct or indirect. The words “upper”, “lower”, “left”, “right”, or the like are merely used to indicate a relative positional relationship, and when an absolute position of the described object is changed, the relative positional relationship may be changed accordingly.

With the development of the display technology, the thin film transistor liquid crystal display (TFT-LCD) is increasingly applied in the current display field due to the characteristics of small size, low power consumption, free of radiation, and the like.

The liquid crystal display panel includes a color filter substrate and an array substrate disposed opposite to each other, and a liquid crystal layer between the color filter substrate and the array substrate. Manufacturing of the color filter substrate generally includes the processes of providing: a black matrix layer—a blue color filter layer-a green color filter layer—a red color filter layer—an over coating (OC)—a post spacer (PS). The post spacer is configured to provide support for the display panel when the color filter substrate and the array substrate are aligned and assembled. If the post spacer can be formed synchronously with other structures in the manufacturing process of the color filter substrate, the manufacturing process will be simplified, thereby greatly improving the manufacturing efficiency of the display panel.

Nowadays, simplifying the manufacturing process of the post spacer has gradually become a development trend in the field of TFT-LCDs. For example, the post spacer may be formed by superposing color filters. For example, the color filter substrate includes a red color filter layer, a blue color filter layer and a green color filter layer, while the post spacer includes three spacer layers which are formed synchronously with the red color filter layer, the green color filter layer, and the blue color filter layer, respectively, thereby saving a separate manufacturing process for the post spacer. However, due to the limited types of color filter layers in the color filter substrate, a superposition height of the post spacer is limited, which cannot satisfy the requirement on segment difference of post spacers with different heights among a plurality of post spacers. Further, the elasticity requirement of the post spacer cannot be satisfied, leading to an unsatisfactory supporting effect of the post spacer, and finally, good alignment and assembly of the color filter substrate and the array substrate cannot be ensured.

To solve at least one of the above technical problems, an embodiment of the present disclosure provides a display panel which can not only simplify the manufacturing process of the color filter substrate, but also enable the post spacer to satisfy the alignment and assembly requirement of the color filter substrate and the array substrate in the display panel.

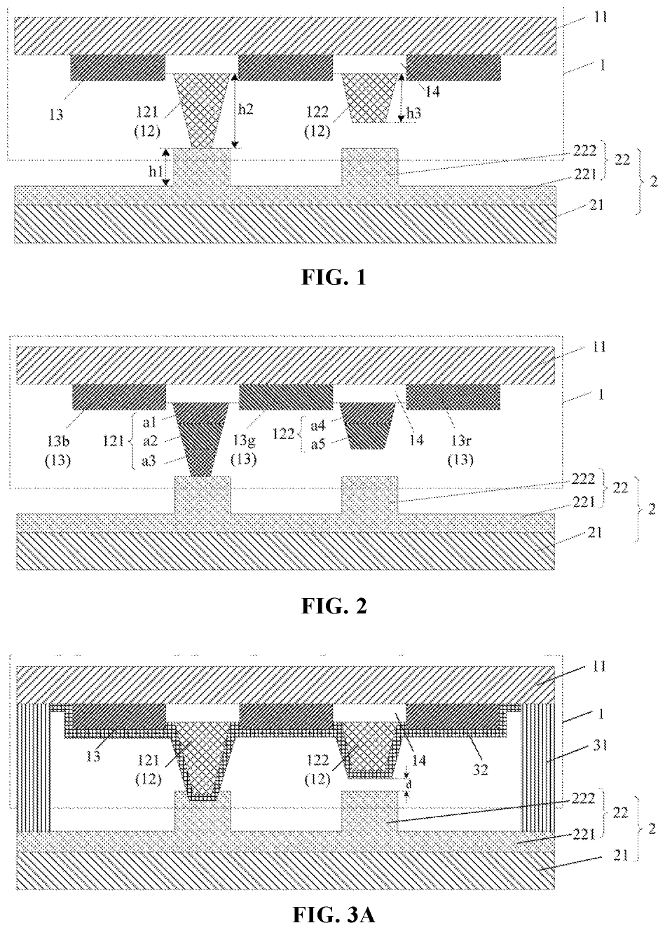

FIG. 1 is a schematic structural diagram of a display panel according to an embodiment of the present disclosure. As shown in FIG. 1, the display panel includes a color filter substrate 1 and an array substrate 2 disposed opposite to each other, and a liquid crystal layer (not shown) between the color filter substrate 1 and the array substrate 2.

The color filter substrate 1 includes a first substrate 11, a plurality of spacer pillars 12, and a plurality of color filter layers 13. The spacer pillars 12 and the color filter layers 13 are disposed on a side of the first substrate 11 facing the array substrate 2, and the first substrate 11 includes a display region including a plurality of pixel regions and a spacing region between adjacent pixel regions. Each spacer pillar 12 is located in the spacing region, and each pixel region is provided with a color filter layer 13. Each spacer pillar 12 includes at least one spacer layer made of the same material as the color filter layer 13 in one of the pixel regions.

The array substrate 2 includes a second substrate 21 and a support layer 22. The support layer 22 is disposed on a side of the second substrate 21 facing the color filter substrate 1. The support layer 22 includes a body layer 221 and a plurality of protrusions 222 on a side of the body layer 221 away from the second substrate 21, where at least one of the protrusions 222 is each disposed opposite to one of the spacer pillars 12. At least one of the spacer pillars 12 is in direct contact with the corresponding protrusion 222 to be supported on the protrusion 222.

It should be noted that the display region may be provided with a plurality of color filter layers 13 of different colors, such as a blue color filter layer, a green color filter layer, and a red color filter layer. Each spacer layer in the spacer pillar 12 may be made of the same material as the color filter layer 13 in one of the pixel regions. In other words, each spacer layer may be formed synchronously with one of the blue color filter layer, the green color filter layer, or the red color filter layer.

In the display panel provided in the embodiments of the present disclosure, each spacer pillar 12 includes at least one spacer layer made of the same material as the color filter layer 13 in one of the pixel regions. Therefore, each spacer layer may be manufactured synchronously with the color filter layer 13 in one of the pixel regions, saving a separate manufacturing step for the spacer pillars 12. In addition, at least one of the spacer pillars 12 is supported on the protrusion 222, which makes up for the limited height of the spacer pillar 12 due to the limited types of color filter layers 13 in the display region. The spacer pillars 12 and the protrusions 222 of the support layer 22 are combined to form a support structure, to provide stable support for the display panel.

In some embodiments, the protrusions 222 have a hardness lower than that of the spacer layer, so that a support structure formed by the spacer pillars 12 and the support layer 22 can not only provide a sufficient support force, but also satisfy the elastic requirement of the support structure. The hardness is generally used to characterize the ability of an object to resist penetration of a hard object into its surface, and a higher hardness means higher resistance to deformation of the object.

In some embodiments, the protrusions 222 are made of a material including an organic material, such as a resin material, so that when the spacer pillar 12 is supported on the protrusion 222, the elasticity of the support structure is increased, and the supporting effect of the support structure is improved.

In some embodiments, the body layer 221 and the protrusions 222 form an integral structure. In other words, in the manufacturing process of the support layer 22, the body layer 221 and the protrusions 222 may be formed simultaneously by patterning the same material layer.

In some embodiments, a ratio of a height of each spacer pillar to a height of the corresponding protrusion is 0.5 to 1.3, so as to ensure a stable support force provided by the support structure, as well as certain elasticity. For example, the ratio of the height of each spacer pillar to the height of the corresponding protrusion is 0.5 or 0.8 or 1 or 1.3.

In some embodiments, the protrusion 222 has a height h1 ranging from 1.4 μm to 1.6 μm. For example, as shown in FIG. 1, the protrusion 222 has a height h1 of 1.5 μm. A segment difference is provided between the body layer 221 and the protrusions 222, and the specific range of the segment difference is not limited in the embodiments of the present disclosure. It should be noted that the height h1 of the protrusion 222 is a height in a natural state without squeezing.

As shown in FIG. 1, the color filter substrate 1 further includes a black matrix 14 in the spacing region, which can prevent crosstalk between different pixel regions. Each spacer pillar 12 is located on a side of the black matrix 14 away from the first substrate 11, and an orthographic projection of the black matrix 14 on the first substrate 11 covers an orthographic projection of the spacer pillar 12 on the first substrate 11, so as to prevent the spacer pillar 12 from affecting the display effect.

In some embodiments, each spacer pillar 12 is disposed opposite to one of the protrusions 222; and the plurality of spacer pillars 12 on the color filter substrate 1 include at least one main spacer pillar 121 and a plurality of auxiliary spacer pillars 122. As shown in FIG. 1, each main spacer pillar 121 is in direct contact with an opposite protrusion 222; and each auxiliary spacer pillar 122 is spaced apart from the opposite protrusion 222.

In some embodiments, as shown in FIG. 1, the main spacer pillar 121 has a height h2 ranging from 1.5 μm to 1.85 μm, and the auxiliary spacer pillar 122 has a height h3 ranging from 0.8 μm to 1.4 μm. For example, the main spacer pillar 121 has a height h2 of 1.82 μm, the auxiliary spacer pillar 122 has a height h3 of 1.36 μm, and a segment difference of 0.46 μm is provided between the main spacer pillar 121 and the auxiliary spacer pillar 122. It should be noted that the height h2 of the main spacer pillar 121 and the height h3 of the auxiliary spacer pillar 122 are heights in a natural state without squeezing.

In one example, the number of main spacer pillars 121 in the color filter substrate takes 1% to 10% of the total number of spacer pillars 12. For example, 96 spacer pillars 12 are provided, including two main spacer pillars 121, where orthographic projections of the two main spacer pillars on the first substrate 11 have a total area of 126.5 μm²; and 94 auxiliary spacer pillars 122, where orthographic projections of the 94 auxiliary spacer pillars on the first substrate 11 have a total area of 5943.6 μm².

In some embodiments, the color filter substrate 1 includes color filter layers 13 of N colors; each spacer layer corresponds to a color filter layer of one color, and different spacer layers in the same spacer pillar 12 correspond to color filter layers 13 of different colors. Each spacer layer has the same thickness as the corresponding color filter layer 13. The main spacer pillar 121 includes N spacer layers, while each auxiliary spacer pillar 122 includes M spacer layers, where M and N are both positive integers, and M<N.

FIG. 2 is a schematic structural diagram of another display panel according to an embodiment of the present disclosure. In one example, as shown in FIG. 2, the color filter substrate 1 includes color filter layers of three colors, i.e., a red color filter layer 13r, a blue color filter layer 13g, and a green color filter layer 13b. The main spacer pillar 121 includes three spacer layers, that is, a first spacer layer a1, a second spacer layer a2, and a third spacer layer a3 sequentially arranged in a direction away from the black matrix 14. The auxiliary spacer pillar 122 includes two spacer layers, that is, a fourth spacer layer a4 and a fifth spacer layer a5 sequentially arranged in a direction away from the black matrix 14. Each of the above spacer layers is made of the same material and has the same thickness as the color filter layer 13 in one of the pixel regions.

In the above example, each of the three spacer layers of the main spacer pillar 121 corresponds to a color filter layer 13 of one color. As shown in FIG. 2, the first spacer layer a1 may be made of the same material and have the same thickness as the blue color filter layer 13b, the second spacer layer a2 may be made of the same material and have the same thickness as the green color filter layer 13g, and the third spacer layer a3 may be made of the same material and have the same thickness as the red color filter layer 13r. In the embodiments of the present disclosure, the order of the three colors of color filter layers in the main spacer pillar 121 is not limited. For example, it is also possible that the first spacer layer a1 is made of the same material and have the same thickness as the red color filter layer 13r, the second spacer layer a2 is made of the same material and have the same thickness as the blue color filter layer 13b, and the third spacer layer a3 is made of the same material and have the same thickness as the green color filter layer 13g. For the two colors of color filter layers 13 in the auxiliary spacer pillar 122, the fourth spacer layer a4 may be made of the same material and have the same thickness as the blue color filter layer 13b, and the fifth spacer layer a5 may be made of the same material and have the same thickness as the green color filter layer 13g. Also, the materials of the color filter layers respectively used for the fourth spacer layer a4 and the fifth spacer layer a5, as well as the order of the two spacer layers in the auxiliary spacer pillar 122, are not limited in the embodiments of the present disclosure.

In one example, the red color filter layer 13r may have a thickness of 2.25 μm, the blue color filter layer 13b may have a thickness of 2.25 μm, the green color filter layer 13g may have a thickness of 2.30 μm, or the three color filter layers 13 may have other thicknesses, which are not limited in the present disclosure.

In one example, since the first spacer layer a1 and the fourth spacer layer a4 are each made of the same material having the same thickness as the blue color filter layer 13b, the two spacer layers may be formed synchronously with the blue color filter layer 13b in the pixel region; since the second spacer layer a2 and the fifth spacer layer a5 are each made of the same material having the same thickness as the green color filter layer 13g, the two spacer layers may be formed synchronously with the green color filter layer 13g in the pixel region; and since the third spacer layer a3 is made of the same material having the same thickness as the red color filter layer 13r, the third spacer layer a3 may be formed synchronously with the red color filter layer 13r in the pixel region. In this manner, the respective spacer layers in the spacer pillars 12 are formed simultaneously with the color filter layers 13 in the pixel region, saving a separate manufacturing step for the spacer pillars 12, and simplifying the manufacturing process of the display panel.

It should be noted that the case of N=3 is taken as an example in the above example for illustration, but in other examples, N may take another value, such as 4.

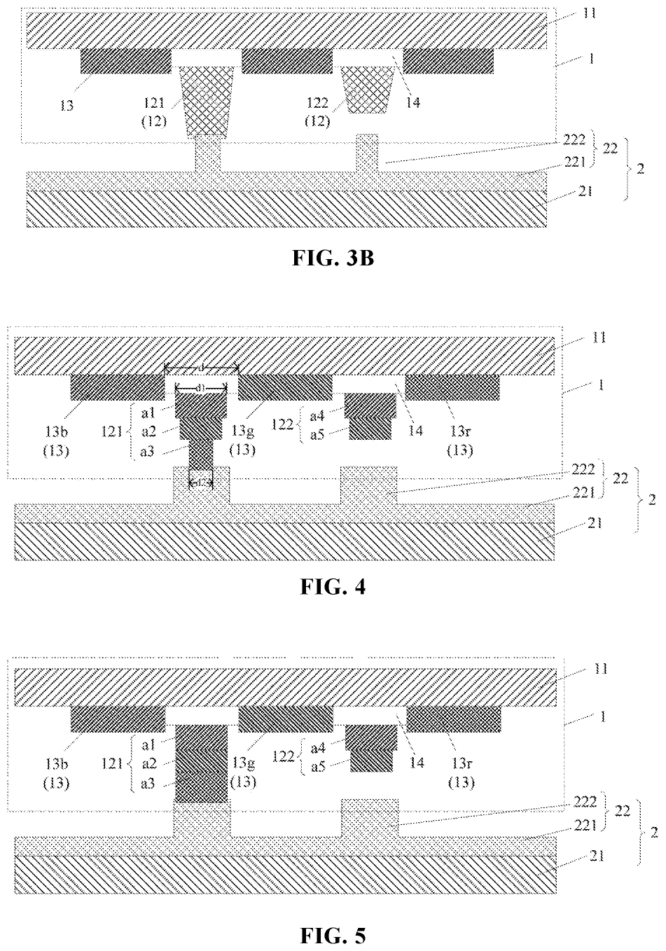

FIGS. 3A and 3B are schematic structural diagrams of another display panel according to an embodiment of the present disclosure. In some embodiments, as shown in FIG. 3A, the display panel further includes a sealant 31 and a protective layer 32.

The sealant 31 is fixedly connected between the color filter substrate 1 and the array substrate 2 to form an annular structure, and the liquid crystal layer is located in a region enclosed by the sealant 31.

The protective layer 32 is located on a side of the color filter substrate 1 facing the array substrate, and covers the color filter layer 13, the black matrix 14 and each spacer layer on the color filter substrate 1, and the protective layer 32 may be an integral structure made of OC glue.

It should be noted that when the protective layer 32 is provided, each spacer pillar further includes a portion of the protective layer 32 corresponding to the spacer layer; and the auxiliary spacer pillar spaced apart from the protrusion 222 means that: a gap d is provided between the protrusion 222 and a portion of the protective layer 32 opposite to the spacer layer in the auxiliary spacer pillar 122. The gap d may be 0.1 μm to 0.15 μm, and for example, as shown in FIG. 3A, d is 0.13 μm. It should be noted that in other figures (for example, FIGS. 2, 3B to 5) of the present disclosure, the protective layer 32 may be provided as well.

In addition, alignment layers (not shown) are provided on a side of the protective layer 32 away from the color filter substrate 1 and on a side of the support layer 22 away from the second substrate 21, respectively, so that liquid crystal molecules in the liquid crystal layer are aligned in a certain direction at a certain angle.

In one example, a thickness of the liquid crystal layer (i.e., cell gap, CG) is 3.5 μm to 3.9 μm at a position corresponding to the pixel region. For example, CG is 3.55 μm.

In some embodiments, as shown in FIG. 3A, the main spacer pillar 121 has a first end face facing the array substrate 2, and the protrusion 222 has a second end face facing the color filter substrate 1. An orthographic projection of the first end face on the first substrate 11 falls within an orthographic projection of the second end face on the first substrate 11. When no external force is applied to the display panel, a certain mutual extrusion force is present between the main spacer pillar 121 and the protrusion 222, so that the resistance to an external force of the display panel can be improved, and the stability of the display panel is increased. For example, as shown in FIG. 3A, when the main spacer pillar 121 and the protrusion 222 presses each other, the second end face of the protrusion 222 is deformed, under the pressing of the first end face, into a depression toward the second substrate 21. For another example, as shown in FIG. 3B, the orthographic projection of the second end face on the first substrate 11 falls within the orthographic projection of the first end face on the first substrate 11, so that under the pressing of the second end face, the first end face of the main spacer pillar 121 is deformed into a depression toward the first substrate 11.

In one example, a mutual pressure is generated between the main pillar spacers 121 and the corresponding protrusion 222, and the main spacer pillar 121 is compressed and deformed under the pressure so that the height h2 is reduced to 1.49 μm from the 1.82 μm in the natural state, generating a deformation amount of 0.33 μm, i.e., 18.1%.

In the above example, as shown in FIGS. 3A and 3B, the first end face of the main spacer pillar 121 and the second end face of the protrusion 222 have different sizes, which can provide a more stable support force than a structure in which the two end faces are completely overlapped.

In another example, where the orthographic projection of the second end face on the first substrate 11 falls within the orthographic projection of the first end face on the first substrate 11, a first limiting groove may be formed in the first end face, so that the second end face of the protrusion 222 is placed into the first limiting groove; or, where the orthographic projection of the first end face on the first substrate 11 falls within the orthographic projection of the second end face on the first substrate 11, a second limiting groove may be formed in the second end face, so that the first end face of the main spacer pillar 121 is placed into the second limiting groove. The formed limiting grooves are both limiting grooves formed in the first end face and the second end face in a non-pressure state, and further, when an external force is applied to the display panel, a mutually embedded structure is formed based on the limiting grooves in the main spacer pillar 121 and the protrusion 222, so that dislocation of the main spacer pillar 121 and the protrusion 222 due to the external force on the display panel can be reduced. Where the first end face or the second end face is formed with the limiting groove, the main spacer pillar 121 and the corresponding protrusion 222 may be designed to be pressed against each other to improve the stability of the display panel.

In some embodiments, orthographic projections of the plurality of spacer layers in at least one of the spacer pillars 12 on the first substrate 11 are sequentially reduced in area in a direction away from the black matrix 14.

FIG. 4 is a schematic structural diagram of another display panel according to an embodiment of the present disclosure. In some embodiments, as shown in FIG. 4, an orthographic projection of the first spacer layer a1 on the first base 11 covers an orthographic projection of the second spacer layer a2 on the first substrate 11, and the orthographic projection of the second spacer layer a2 on the first base 11 covers an orthographic projection of the third spacer layer a3 on the first substrate 11. In other words, the three spacer layers in the main spacer pillar 121 may form a stepped structure. Similarly, the two spacer layers in the auxiliary spacer pillar 122 may also form a stepped structure.

Optionally, a ratio of a width of a spacer layer closest to the black matrix 14 in each spacer pillar 12 to a width of the black matrix 14 is between 0.5 and 1; and in the same spacer pillar 12, a ratio of an area of a spacer layer farthest from the black matrix 14 to an area of the spacer layer closest to the black matrix 14 is between ⅙ and ½, thereby improving the support stability of the post spacer 12. For example, in the main spacer pillar 121 in FIG. 4, a ratio of a width of the first spacer layer a1 to a width of the black matrix 14 is between 0.5 and 1, and a ratio of an area of the third spacer layer a3 to an area of the first spacer layer a1 is between ⅙ and ½; while in the auxiliary spacer pillar 122 in FIG. 4, a ratio of a width of the fourth spacer layer a4 to a width of the black matrix 14 is between 0.5 and 1, and a ratio of an area of the fifth spacer layer a5 to an area of the fourth spacer layer a4 is between ⅙ and ½.

It should be noted that the black matrix 14 is a grid structure having a plurality of first light-shielding strips extending in a first direction and a plurality of second light-shielding strips extending in a second direction. The first direction is an extending direction of gate lines, the second direction is an extending direction of data lines, and the plurality of first light-shielding strips and the plurality of second light-shielding strips are intersected to form the grid structure. For the spacer pillar 12 arranged opposite to each first light-shielding strip, the ratio of a width of a spacer layer to a width of the black matrix 14 refers to a ratio of a dimension of the spacer layer in the second direction to a dimension of the first light-shielding strip in the second direction; and for the spacer pillar 12 arranged opposite to each second light-shielding strip, the ratio of a width of a spacer layer to a width of the black matrix 14 refers to a ratio of a dimension of the spacer layer in the first direction to a dimension of the second light-shielding strip in the first direction.

Apparently, the three spacer layers in the main spacer pillar 121 and/or the two spacer layers in the auxiliary spacer pillar 122 may be formed into other shapes, for example, a structure having a trapezoidal longitudinal section.

It should be noted that the plurality of spacer layers in the main spacer pillar 121 or the auxiliary spacer pillar 122 may form a stepped structure with sequentially decreasing orthographic projections on the first substrate 11, or form a cylinder structure with the same orthographic projection area on the first substrate 11. FIG. 5 is a schematic structural diagram of another display panel according to an embodiment of the present disclosure. In some embodiments, as shown in FIG. 5, orthographic projections of the plurality of spacer layers in the main spacer pillar 121 on the first substrate 11 have the same area.

The orthographic projection of each spacer layer on the first substrate 11 may have a circular shape, a quadrilateral shape or any other polygonal shape, which is not limited in the embodiments of the present disclosure.

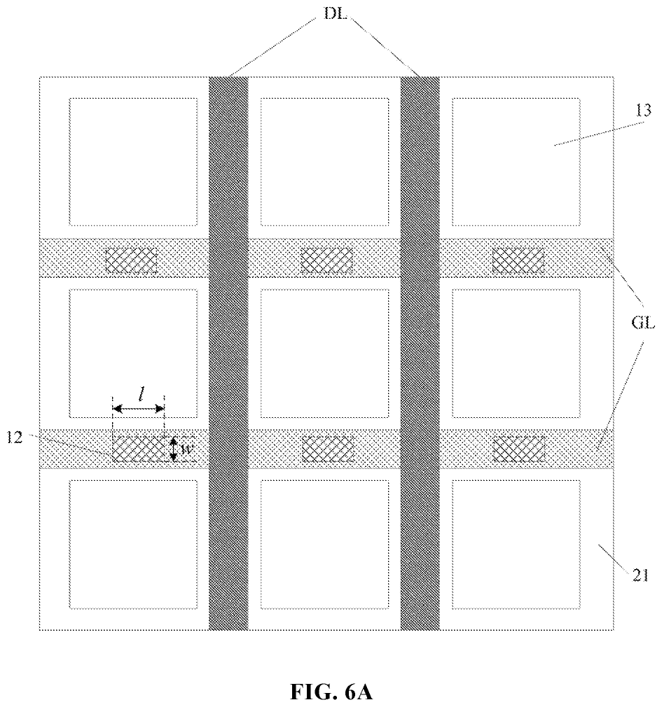

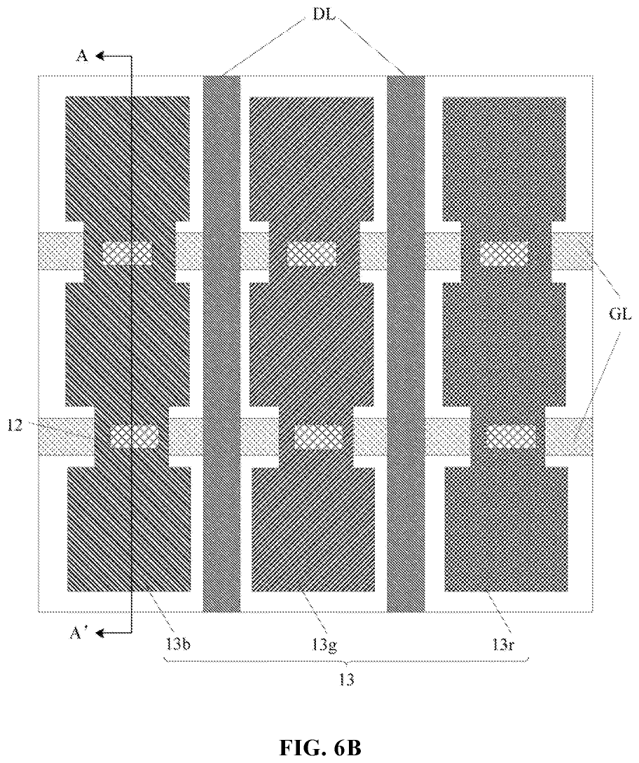

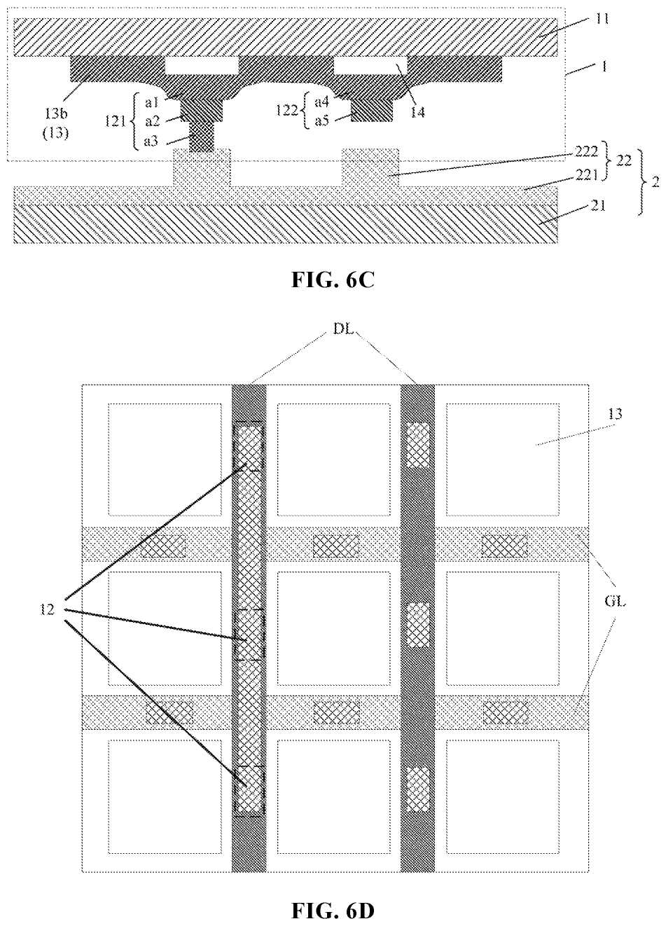

FIG. 6A is a schematic plan view of a display panel according to an embodiment of the present disclosure. FIG. 6A merely illustrates a partial structure of the display panel. As shown in FIG. 6A, the array substrate 2 further includes a plurality of gate lines GL and a plurality of data lines DL on the second substrate 21. The gate lines GL extend in a first direction, and the data lines DL extend in a second direction. It should be noted that a signal line extending in a certain direction does not necessarily mean that the signal line is a straight line, but generally tends to extend in that direction. The plurality of gate lines GL and the plurality of data lines DL are intersected with each other, and an orthographic projection of each gate line GL on the first substrate 11, and an orthographic projection of each data line DL on the first substrate 11 are both located within the spacing region.

The materials of the gate line GL and the data line DL are not particularly limited, and both the gate line GL and the data line DL may include a single metal layer or multiple metal layers. For example, the data line DL includes a stack of MO/Cu/MO, where thicknesses of the metal layers are 150 Å/3000 Å/800 Å in sequence; and the gate line GL may be made of Cu having a thickness between 2500 Å and 3500 Å, for example, 3000 Å.

Since the spacer pillar 12 forms a part of the support structure in the display panel, a larger orthographic projection of the spacer pillar 12 on the first substrate 11 leads to better stability of the support structure. On the other hand, however, provision of the spacer pillar 12 will affect an aperture range of the pixel, and thus an emission amount of the display panel, so the size of the spacer pillar 12 is limited accordingly. In some embodiments, as shown in FIG. 6A, an orthographic projection of at least one of the spacer pillars 12 on the first substrate 11 is located within the orthographic projection of the gate line GL on the first substrate 11. In other words, within the orthographic projection of the gate line GL on the first substrate 11, a size of the spacer pillar 12 in the extending direction of the gate line GL can be increased. With such a structure, the emission efficiency of the display panel will not be influenced while the size of the spacer pillar 12 is increased to ensure the supporting effect.

In some embodiments, at least two adjacent color filter layers 13 of the same color are connected into an integral structure. For example, the color filter layers in a plurality of pixel regions are arranged in multiple rows and columns, where a row direction may be the first direction, a column direction may be the second direction, and color filter layers in the same column have the same color. In this case, at least two color filter layers in the same column are connected into an integral structure.

In one example, the color filter substrate is provided with the plurality of spacer pillars 12, including at least one main spacer pillar 121, where each main spacer pillar 121 is adjacent to a blue color filter layer 13b in the second direction.

It should be noted that the spacer pillar 12 shown in FIG. 6A may be a main spacer pillar or an auxiliary spacer pillar, and regardless of that, the orthographic projection of the spacer pillar on the first substrate 11 may have any shape, such as a quadrangular shape, a circular shape, a semicircular shape, a triangular shape, or the like, which is not limited in the embodiments of the present disclosure. In one example, as shown in FIG. 6A, the orthographic projection of the spacer pillar 12 on the first substrate 11 has a rectangular shape which may have a longer side 1 of 20 μm and a shorter side w of 14 μm. In addition, the two sides of the rectangular shape may have other lengths, which are not limited in the embodiments of the present disclosure.

In some embodiments, at least one of the spacer layers and an adjacent color filter layer may be connected into an integral structure.

FIG. 6B is a schematic plan view of another display panel according to an embodiment of the present disclosure, and FIG. 6C is a schematic sectional view taken along line AA′ in FIG. 6B. In one example, as shown in FIGS. 6B and 6C, taking the leftmost column of pixel regions in FIG. 6B as an example, each of the three pixel regions in this column is provided with a blue color filter layer 13b, and in each of the two spacer pillars between the three blue color filter layers 13b, one spacer layer made of the same material and having the same thickness as the blue color filter layer 13b is provided. Therefore, the three blue color filter layers 13b and the two spacer layers of the same material and thickness in the same column are formed into an integral structure. Likewise, three green color filter layers 13g and two spacer layers of the same material and thickness in the same column may be formed into an integral structure, and three red color filter layers 13r and two spacer layers of the same material and thickness in the same column may be formed into an integral structure.

It should be noted that although only a pixel array of three rows and three columns is shown in FIG. 6B, in practical applications, the number of rows and the number of columns of pixel regions arranged in an array in the display panel are both far greater than three. In any row or column of the multiple rows or columns of pixel regions, the color filter layers may have the same color and form an integral structure. Meanwhile, for the same column, the spacer pillar between adjacent pixel regions is provided with a spacer layer of the same material and thickness as the color filter layer in the pixel region, which may also form an integral structure with the color filter layer, thereby forming a continuous film layer extending in the column direction.

It should be noted that the spacer layer forming an integral structure with the color filter layer may be a spacer layer in the main spacer pillar 121, or a spacer layer in the auxiliary spacer pillar 122. For example, as shown in FIGS. 6B and 6C, one column of pixel regions are each provided with a blue color filter layer, where either the main spacer pillar 121 or the auxiliary spacer pillar 122 may be disposed between the pixel regions in the column, and the first spacer layer a1 in the main spacer pillar 121, and the fourth spacer layer a4 in the auxiliary spacer pillar 122 are both connected to the blue color filter layer into an integral structure.

FIG. 6D is a schematic plan view of another display panel according to an embodiment of the present disclosure. In one example, as shown in FIG. 6D, data lines DL are disposed opposite to a plurality of spacer pillars 12, where spacer layers made of the same material in the plurality of spacer pillars 12 disposed opposite to the same data line DL may be connected into an integral structure.

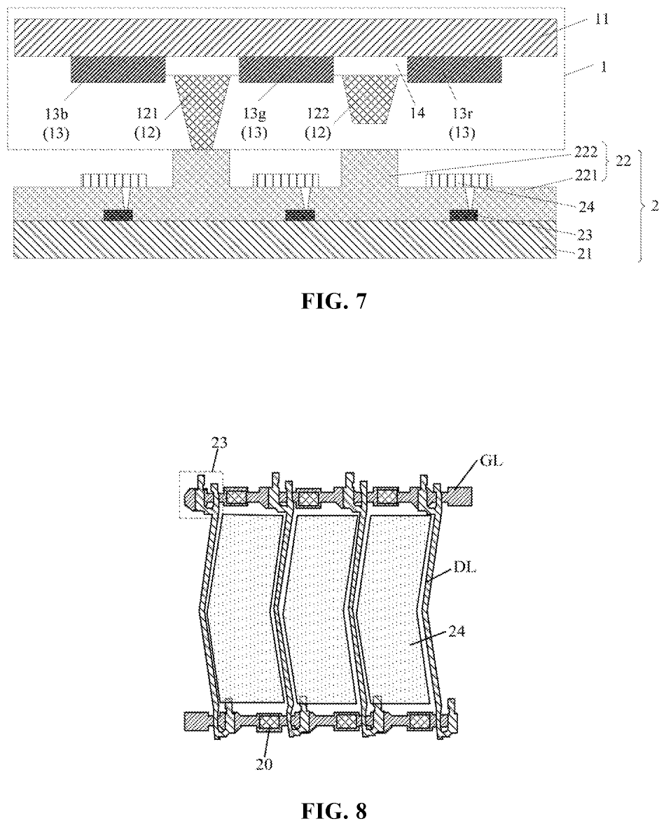

FIG. 7 is a schematic structural diagram of another display panel according to an embodiment of the present disclosure. In some embodiments, as shown in FIG. 7, the array substrate 2 further includes a thin film transistor 23, and a pixel electrode 24. The thin film transistor 23 is located between the second substrate 21 and the support layer 22. The pixel electrode 24 is located on a side of the support layer 22 away from the second substrate 21, and connected to a drain of the thin film transistor 23 through a via in the body layer 221. The pixel electrode 24 may be made of a transparent material, such as ITO (Indium Tin Oxide). The pixel electrode 24 may have a thickness of 350 Å to 450 Å, such as 400 Å. Apparently, the array substrate 2 may further include other structures not shown in the figures, such as a common electrode.

FIG. 8 is a schematic plan view of another display panel according to an embodiment of the present disclosure. In some embodiments, as shown in FIG. 8, the orthographic projection of the spacer pillar 12 on the first substrate 11 is not overlapped with an orthographic projection of the thin film transistor 23 on the first substrate 11. Taking FIG. 8 as an example, pixel electrodes 24 and color filter layers 13 are provided in one-to-one correspondence. That is, the pixel electrodes 24 are arranged in multiple rows and columns, with each pixel electrode 24 connected to one thin film transistor 23, gates of thin film transistors 23 connected to the same row of pixel electrodes 24 are connected to the same gate line GL, and sources of two thin film transistors 23 connected to the two adjacent pixel electrodes 24 in the same column are connected to two adjacent data lines DL, respectively. In this case, as shown in FIG. 8, the thin film transistors 23 are provided at a lower left corner and an upper right corner of the pixel electrode 24, and support structures 20 may be provided at an upper left corner and a lower right corner of the pixel electrode 24.

Apparently, the plurality of pixel electrodes 24 and thin film transistors 23 may be connected in other manners. For example, each pixel electrode 24 is connected to one thin film transistor 23, gates of thin film transistors 23 connected to the same row of pixel electrodes 24 are connected to the same gate line GL, and sources of thin film transistors 23 connected to the same column of pixel electrodes 24 are connected to the same data line DL. In this case, the thin film transistors 23 are provided at an upper left corner and a lower left corner of the pixel electrode 24, while the support structures 20 may be provided at an upper right corner and a lower right corner of the pixel electrode.

Each gate line GL may have a uniform width throughout, or as shown in FIG. 8, have a varying width at different positions. As shown in FIG. 8, the gate line GL may be appropriately widened at positions corresponding to the support structure 20 or the thin film transistor 23, and narrowed at positions without the support structure 20 or the thin film transistor 23. On the one hand, wider positions may have a reduced resistance, and on the other hand, narrower positions can leave more space for openings, thereby improving the display effect of the display panel.

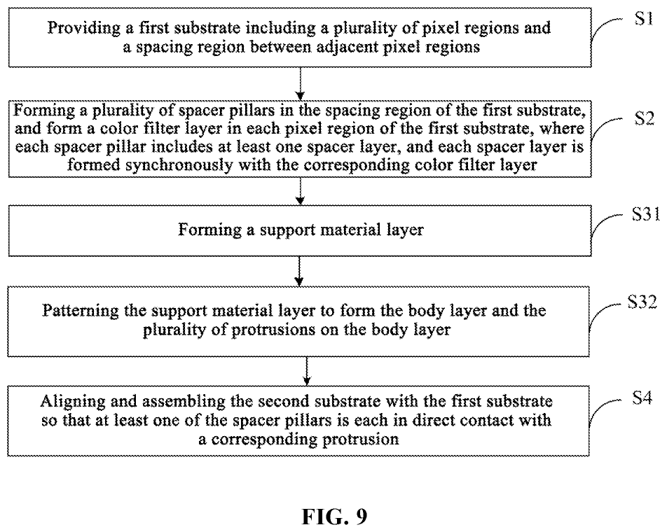

FIG. 9 is a schematic flowchart of a method for manufacturing a display panel according to an embodiment of the present disclosure. As shown in FIG. 9, the method for manufacturing a display panel includes the following steps S1 to S4.
At S1, providing a first substrate including a plurality of pixel regions and a spacing region between adjacent pixel regions.
At S2, forming a plurality of spacer pillars in the spacing region of the first substrate, and forming a color filter layer in each pixel region of the first substrate, where each spacer pillar includes at least one spacer layer, and each spacer layer is formed synchronously with the corresponding color filter layer.
At S3, providing a second substrate, and forming a support layer on the second substrate. The support layer includes a body layer and a plurality of protrusions on a side of the body layer away from the second substrate, and at least one of the protrusions corresponds to one of the spacer pillars.

The step of forming the support layer on the second substrate in S3 may include the following steps S31 to S32.
S31, forming a support material layer.
At S32, patterning the support material layer to form the body layer and the plurality of protrusions on the body layer.
S4, aligning and assembling the second substrate with the first substrate, so that at least one of the spacer pillars is each in direct contact with a corresponding protrusion.

According to the method for manufacturing a display panel according to the embodiment of the present disclosure, each spacer layer in the spacer pillars is made of the same material as the color filter layer in one of the pixel regions, and can be produced in the same process as the color filter layer, thereby saving a separate manufacturing step for the spacer pillars. The spacer pillars are supported on the protrusions, i.e., in direct contact with the protrusions, so that the defect of a limited height of the spacer pillar due to the limited types of color filter layers in the pixel regions is overcome; and, the body layer and the plurality of protrusions are formed in the same process. The display panel formed in the above method can ensure the supporting effect of the support structure consisting of the spacer pillars and the support layer, provide a sufficient support force, and simplify the manufacturing process of the display panel.

An embodiment of the present disclosure further provides a display apparatus including the display panel as described above.

The display apparatus may be an electronic paper, a mobile phone, a tablet, a television, a monitor, a laptop, a digital album, a navigator or any other product or component having a display function, which is not limited in the present disclosure.

It will be appreciated that the above implementations are merely exemplary implementations for the purpose of illustrating the principle of the present disclosure, and the present disclosure is not limited thereto. It will be apparent to those of ordinary skill in the art that various modifications and variations may be made without departing from the spirit or essence of the present disclosure. Such modifications and variations should also be considered as falling into the protection scope of the present disclosure.

1. A display panel, comprising an array substrate and a color filter substrate opposite to each other, wherein
the color filter substrate comprises a first substrate, a plurality of spacer pillars, and a plurality of color filter layers, the spacer pillars and the color filter layers are on a side of the first substrate facing the array substrate, and the first substrate comprises a plurality of pixel regions and a spacing region between adjacent pixel regions; each spacer pillar is in the spacing region, and each pixel region is provided with the color filter layer;
each spacer pillar comprises at least one spacer layer each made of the same material as the color filter layer in one of the pixel regions;
the array substrate comprises a second substrate and a support layer, wherein the support layer is on a side of the second substrate facing the color filter substrate, and comprises a body layer and a plurality of protrusions on a side of the body layer away from the second substrate, and at least one of the protrusions is each opposite to one of the spacer pillars; and
at least one of the spacer pillars is each in direct contact with a corresponding protrusion.

2. The display panel according to claim 1, wherein the protrusions have a hardness lower than a hardness of the spacer layer.

3. The display panel according to claim 1, wherein the protrusions are made of a material comprising an organic material.

4. The display panel according to claim 1, wherein the body layer and the protrusions form an integral structure.

5. The display panel according to claim 1, wherein a ratio of a height of each spacer pillar to a height of the corresponding protrusion is 0.5 to 1.3.

6. The display panel according to claim 1, wherein the color filter substrate further comprises a black matrix in the spacing region; and
each spacer pillar is on a side of the black matrix away from the first substrate, and an orthographic projection of the black matrix on the first substrate covers an orthographic projection of the spacer pillar on the first substrate.

7. The display panel according to claim 1, wherein each spacer pillar is opposite to one of the protrusions;
the plurality of spacer pillars comprise at least one main spacer pillar and a plurality of auxiliary spacer pillars;
each main spacer pillar is in direct contact with a protrusion opposite to the main spacer pillar; and
each auxiliary spacer pillar is spaced apart from a protrusion opposite to the auxiliary spacer pillar.

8. The display panel according to claim 7, wherein the color filter substrate comprises color filter layers of N colors; each spacer layer corresponds to a color filter layer of one color, and different spacer layers in the same spacer pillar correspond to color filter layers of different colors; each spacer layer is made of the same material and has the same thickness as the corresponding color filter layer; and
the main spacer pillar comprises N spacer layers, and each auxiliary spacer pillar comprises M spacer layers, where M and N are both positive integers, and M<N.

9. The display panel according to claim 8, wherein
orthographic projections of the N spacer layers in the main spacer pillar on the first substrate have the same area.

10. The display panel according to claim 6, wherein each spacer pillar comprises a plurality of spacer layers, and
orthographic projections of the plurality of spacer layers in each of at least one of the spacer pillars on the first substrate are sequentially reduced in area in a direction away from the black matrix.

11. The display panel according to claim 10, wherein a ratio of a width of a spacer layer closest to the black matrix in each spacer pillar to a width of the black matrix is between 0.5 and 1; and
a ratio of an area of a spacer layer farthest from the black matrix in the spacer pillar to an area of the spacer layer closest to the black matrix is between ⅙ and ½.

12. The display panel according to claim 1, wherein
at least two adjacent color filter layers of the same color are connected into an integral structure.

13. The display panel according to claim 1, wherein
at least one of the spacer layers and an adjacent color filter layer are connected into an integral structure.

14. The display panel according to claim 1, wherein
the array substrate further comprises a plurality of gate lines and a plurality of data lines on the second substrate, the plurality of gate lines and the plurality of data lines are intersected with each other, and an orthographic projection of each gate line on the first substrate and an orthographic projection of each data line on the first substrate are both within the spacing region; and
an orthographic projection of at least one of the spacer pillars on the first substrate is within the orthographic projection of the gate line on the first substrate.

15. The display panel according to claim 1, wherein the array substrate further comprises a thin film transistor, and a pixel electrode;
the thin film transistor is between the second substrate and the support layer; and
the pixel electrode is on a side of the support layer away from the second substrate, and connected to a drain of the thin film transistor through a via in the body layer.

16. The display panel according to claim 15, wherein
the orthographic projection of the spacer pillar on the first substrate is not overlapped with an orthographic projection of the thin film transistor on the first substrate.

17. A method for manufacturing a display panel, comprising:
providing a first substrate comprising a plurality of pixel regions and a spacing region between adjacent pixel regions;
forming a plurality of spacer pillars in the spacing region of the first substrate, and forming a color filter layer in each pixel region of the first substrate, wherein each spacer pillar comprises at least one spacer layer, and each spacer layer is formed synchronously with a corresponding color filter layer;
providing a second substrate, and forming a support layer on the second substrate, wherein the support layer comprises a body layer and a plurality of protrusions on a side of the body layer away from the second substrate, and at least one of the protrusions is each opposite to one of the spacer pillars; and
aligning and assembling the second substrate with the first substrate, so that at least one of the spacer pillars is each in direct contact with a corresponding protrusion.

18. The method for manufacturing a display panel according to claim 17, wherein forming the support layer on the second substrate comprises:
forming a support material layer, and
patterning the support material layer to form the body layer and the plurality of protrusions on the body layer.

19. A display apparatus, comprising the display panel according to claim 1.
